(19) United States
(12) Patent Application Publication
(10) Pub. No.: US 2026/0103792 A1
(43) Pub. Date: Apr. 16, 2026

(54) SEMICONDUCTOR PROCESSING APPARATUS AND RELATED METHODS

(71) Applicant: Taiwan Semiconductor Manufacturing Company Limited, Hsin-Chu (TW)

(72) Inventors: Ting-Jyun JIANG, Taoyuan City (TW); Liu YUNG-TSUN, Taipei City (TW); Kuang-Wei CHENG, Hsinchu City (TW); Hsing-Chieh LEE, Hsinchu City (TW)

(21) Appl. No.: 18/915,422

(22) Filed: Oct. 15, 2024

(51) Int. Cl. C23C 16/04; H01L 21/67

(52) U.S. Cl. CPC C23C 16/045; H10P 72/0434; H10P 72/0448

(57) ABSTRACT

An apparatus is provided. The apparatus includes: a wafer support structure; a chamber over the wafer support structure, the chamber defining an exhaust opening that overlies the wafer support structure; and a gas flow control structure between the wafer support structure and the exhaust opening. The gas flow control structure includes: a first region defining a first opening having a first size; a third region defining a plurality of third openings each having a third size, the first region being more proximal a center of the gas flow control structure than the third region; and a second region between the first region and the third region, the second region defining a plurality of second openings each having a second size, the second size exceeding the third size, the first size exceeding the second size.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic view of an apparatus for thermally processing a semiconductor wafer, in accordance with some embodiments.

FIG. 1B illustrates a diagrammatic view of a semiconductor device, in accordance with some embodiments.

FIG. 2A illustrates a schematic view of an apparatus for thermally processing a semiconductor wafer during a cooling operation, in accordance with some embodiments.

FIG. 2B illustrates a diagrammatic side view of non-uniformity of a layer on a semiconductor wafer following a cooling operation, in accordance with some embodiments.

FIG. 2C illustrates a diagrammatic top view of a semiconductor wafer following a cooling operation, in accordance with some embodiments.

FIG. 3A illustrates a schematic perspective view of a gas deflector, in accordance with some embodiments.

FIG. 3B illustrates a schematic top view of a region of the gas deflector, in accordance with some embodiments.

FIG. 3C illustrates a schematic top view of a region of the gas deflector, in accordance with some embodiments.

FIG. 4 is a flow diagram illustrating a method, in accordance with some embodiments.

FIG. 5 is a flow diagram illustrating a method, in accordance with some embodiments.

FIG. 6 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

With progress in advanced semiconductor process nodes, photoresist thickness suffers radial non-uniformity due to a gas deflector design of a thermal processing apparatus. Some exhaust modules include a gas deflector that has radial flow channels, each of which has the largest holes arrayed at a periphery thereof and smaller holes arrayed inward from the periphery. Each hole can cause a reverse stagnation point effect by fluid dynamic theory, which can be observed on a wafer map. Namely, lowest fluid velocity is present immediately under each hole. Considering the reverse stagnation point effect of each hole and overall arrangement of holes, fluid velocity distribution has radial non-uniformity, which is depicted via a radially non-uniform wafer map. In addition to the above, the largest holes being arranged at the periphery and the smaller holes being arranged at the inside result in the lowest fluid velocity being at or near the center of the semiconductor wafer. The lower fluid velocity results in increased photoresist thickness at the center. This is supported by computer simulation.

In embodiments of the disclosure, the gas deflector has holes arranged such that flow resistance decreases from a periphery of the gas deflector toward a center thereof. Namely, as cooling gas flows into a space between a wafer being cooled and the gas deflector, the cooling gas is drawn up through the gas deflector at a more uniform flow rate across the surface of the wafer facing the gas deflector. In some embodiments, holes at the periphery of the gas deflector are smaller than holes in an intermediate region of the gas deflector, which are smaller than a hole(s) at the center of the gas deflector. In some embodiments, radius or area of the holes of the gas deflector increases continuously and gradually from the periphery to the center. The arrangement of holes results in improved uniformity of a cooled film layer (e.g., photoresist or polymer), which can result in improved uniformity of features (e.g., vias, fins, source/drains, or the like) formed via patterning and/or etching of the cooled layer. The arrangement can reduce formation and severity of a reverse stagnation zone(s) having reduced fluid velocity at the center of the semiconductor wafer, resulting in improved uniformity of thickness of the formed film layer.

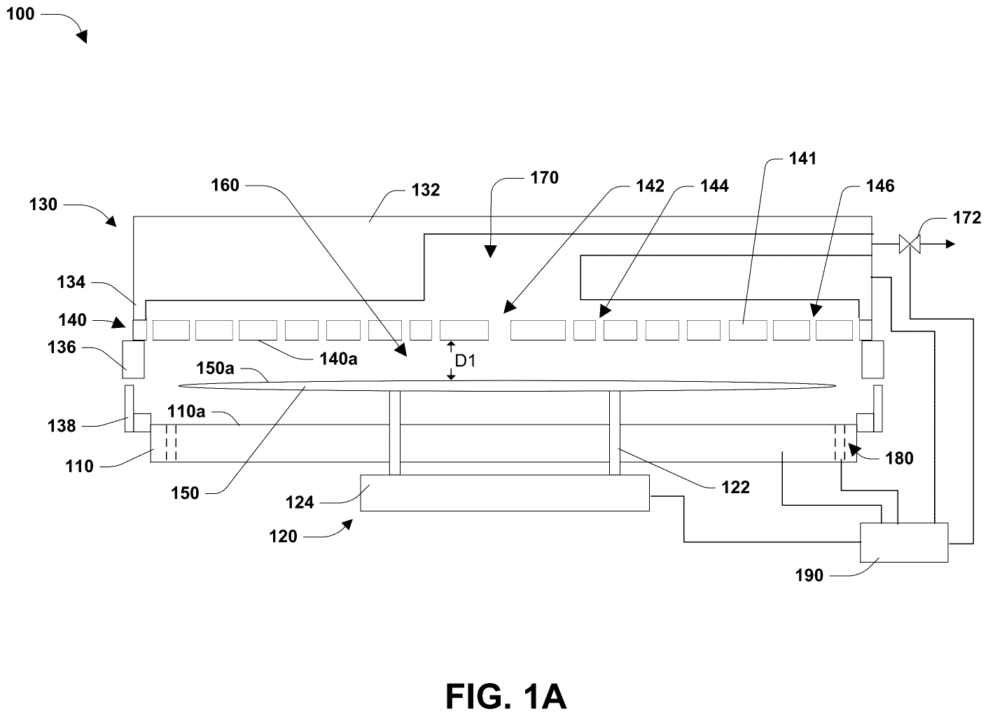

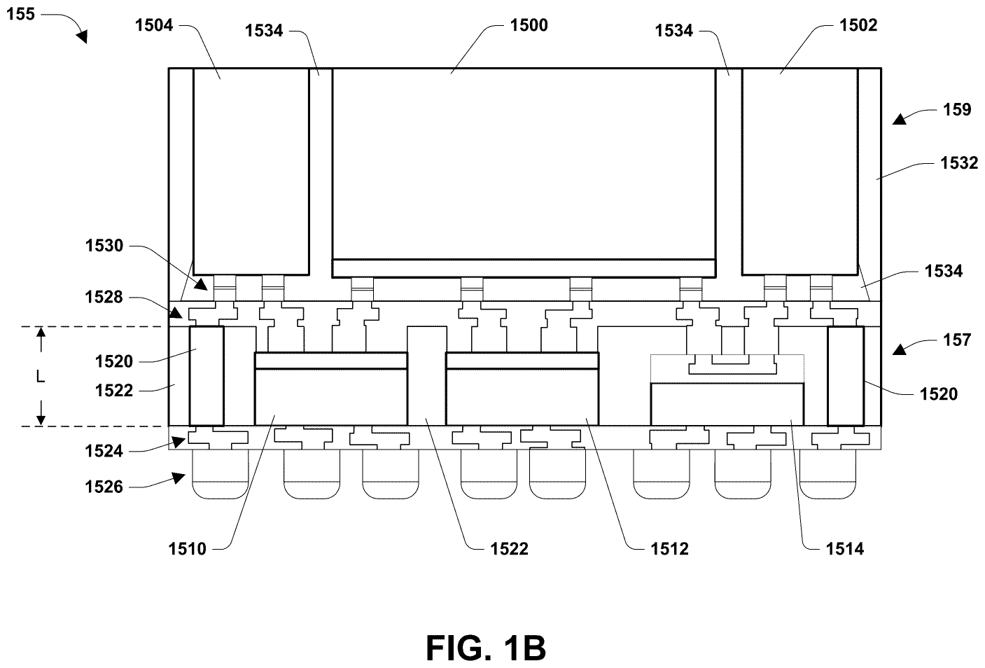

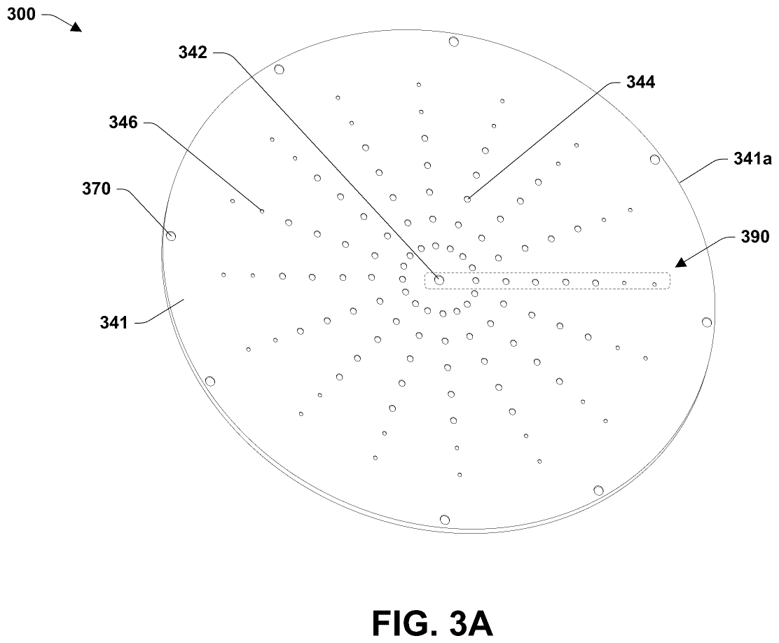

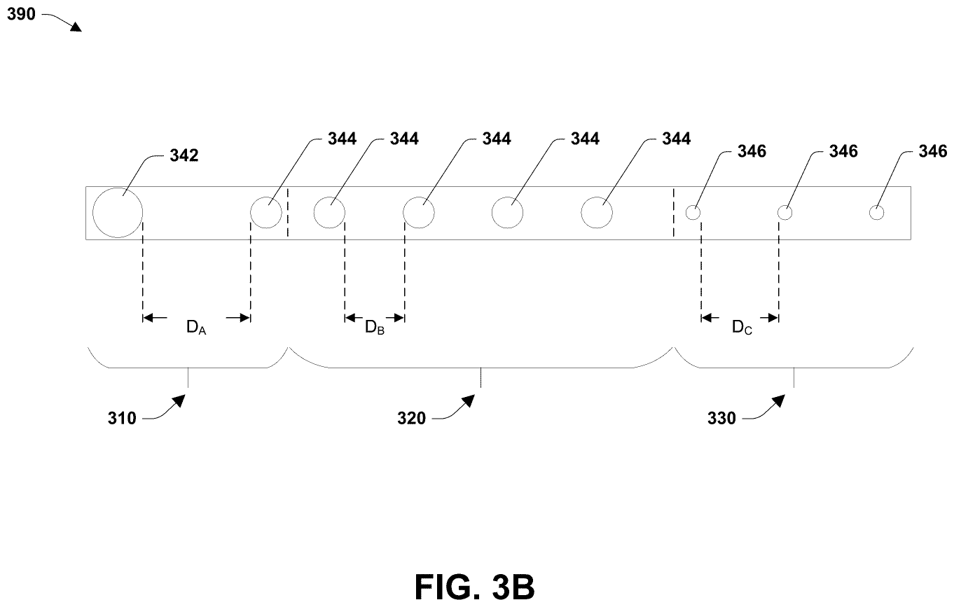

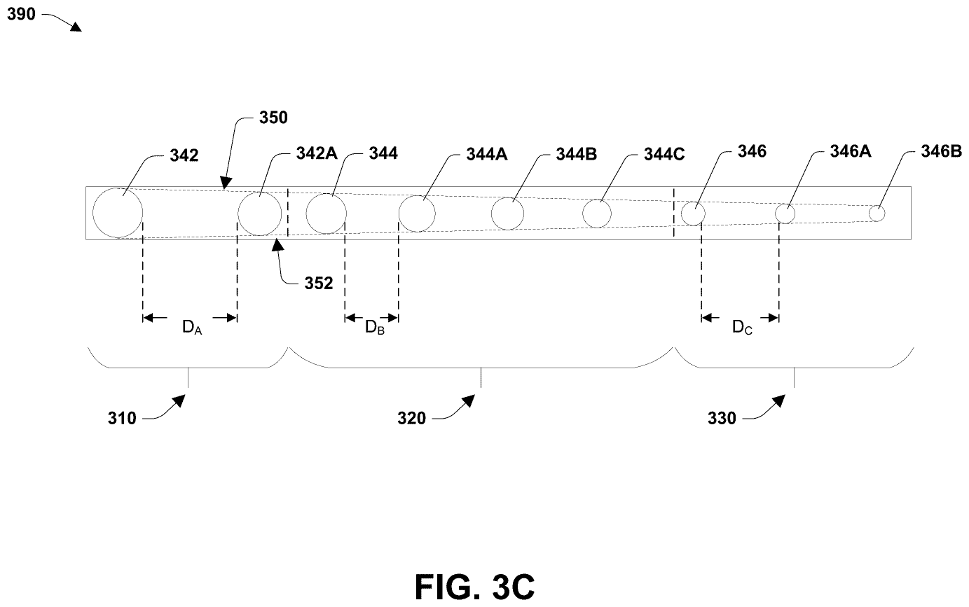

FIG. 1A illustrates an apparatus 100 that is operable to thermally process a semiconductor wafer 150, according to some embodiments. The apparatus 100 can be referred to as a “thermal processing apparatus 100” throughout the description. The apparatus 100 is described in detail herein to provide context for understanding embodiments of a gas deflector or “gas flow control structure” 140 thereof and related methods that are described with reference to FIGS. 3A-6.

The apparatus 100 is operable to thermally process the semiconductor wafer 150. Thermal processing may include heating the semiconductor wafer 150, cooling the semiconductor wafer 150, or both. In some embodiments, the apparatus 100 is a standalone unit. In some other embodiments, the apparatus 100 is one of many stages in a larger processing apparatus. For example, the apparatus 100 may be a thermal processing stage in a coating system, which may further be one of a plurality of apparatuses of a semiconductor processing tool, such as a development and coating tool.

The coating system may be operable to form one or more thin layers of material, such as hard mask (e.g., spin-on carbon), photosensitive resist (or “photoresist” or “resist”), bottom antireflective coating (BARC), one or more polymers, and the like. For example, the coating system may include one or more pairs of a coating apparatus and a thermal processing apparatus similar to the apparatus 100. Each of the pairs may be operable to coat, heat and cool an individual thin layer of the material on the semiconductor wafer 150.

The coating apparatus receives the semiconductor wafer 150, e.g., from a wafer carrier. The semiconductor wafer 150 can be a wafer made of silicon or other semiconductor materials. The coating apparatus then coats the semiconductor wafer 150 with a processing liquid, such as photoresist. The coating can be done by spinning the wafer while dispensing the processing liquid, forming a uniform layer of the processing liquid.

The apparatus 100 can perform heating and cooling of the coated semiconductor wafer 150 and the layer of processing liquid thereon. For example, the semiconductor wafer 150 after coating is then placed on a carrier and loaded into the apparatus 100. The apparatus 100 performs a bake of the semiconductor wafer 150, which can be a soft bake. The apparatus 100 heats the wafer to a selected temperature (such as between 90° C. and 130° C.) for a selected amount of time. The bake can remove residual solvent from the processing liquid layer, solidifying the processing liquid layer to form a solid or mostly solid film layer, such as a photoresist layer. The bake can improve adhesion of the film layer to the surface of the semiconductor wafer 150.

During or following the heating, a gas may be flowed over the coated surface 150a (or “surface 150a” or “wafer surface 150a”) of the semiconductor wafer 150. The gas may be supplied from below or beside the semiconductor wafer 150 and may be exhausted from above the semiconductor wafer 150. To control flow rate and uniformity of flow of the gas over the coated surface of the semiconductor wafer 150, the gas may flow through a gas deflector 140 that has holes distributed therethrough. As will be described in greater detail with reference to FIGS. 3A-3C, the arrangement and sizes of the holes are selected to increase uniformity of the flow, which increases uniformity of thickness of the solidified film layer.

Following the bake, the solidified film layer may undergo photolithography, an optional post bake and development to form a patterned film layer. The photolithography, optional post bake and development may be performed outside the pair of coating apparatus and thermal processing apparatus, such as in a photolithography stepper and developing apparatus. The developing apparatus may include a thermal processing apparatus different than the thermal processing apparatus 100 for performing the post bake of the patterned film layer. The patterned film layer may be used as a mask for a subsequent etching operation that removes material of the semiconductor wafer 150 exposed by and below the patterned film layer.

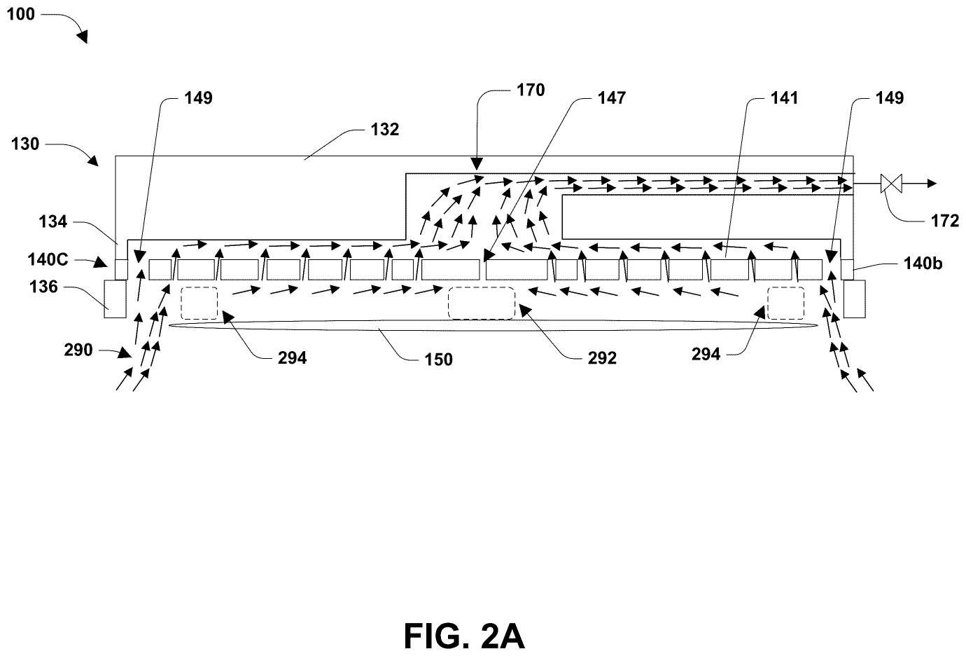

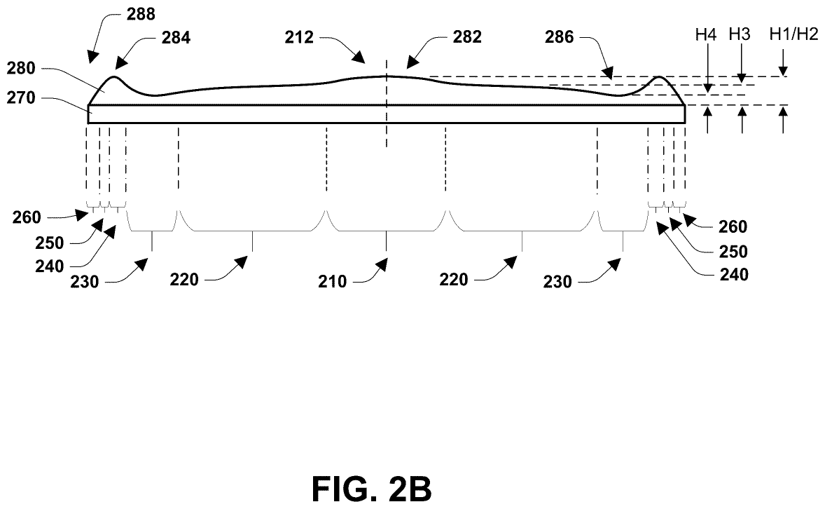

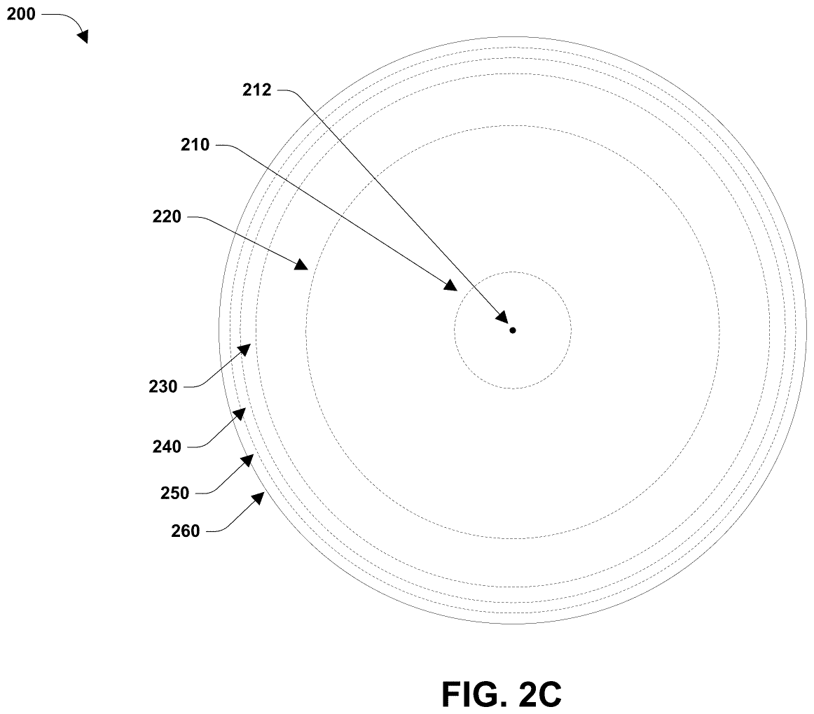

Structure and elements of the thermal processing apparatus 100 are now described in detail with reference to FIG. 1A. A portion 155 of a wafer that can be an embodiment of the semiconductor wafer 150 is described with reference to FIG. 1B. Operation of a thermal processing apparatus is described with reference to FIGS. 2A-2C, with particular attention to stagnation zones or regions 292, 294 and non-uniformity of a film layer 280 that is formed on a wafer 270. Structure and elements of gas deflectors 300 that can reduce formation and severity of stagnation zones and non-uniformity of a formed film layer are described in greater detail with reference to FIGS. 3A-3C.

In FIG. 1A, the thermal processing apparatus 100 includes a wafer support stage 110, a wafer lifting assembly 120, a chamber 130, and a controller 190. In some embodiments, the thermal processing apparatus 100 includes a housing (not shown) or is installed in a housing that has additional thermal processing apparatuses installed therein. In some embodiments, the controller 190 is positioned in the housing or outside the housing. The chamber 130, wafer support stage 110, and wafer lifting assembly 120 may be positioned inside the housing.

The wafer support stage 110 supports the semiconductor wafer 150, which may also be referred to as “the wafer 150.” In some embodiments, the wafer support stage 110 is operable to heat the wafer 150, and can include, for example, one or more heating elements in a rigid plate. The heating element(s) are positioned inside the rigid plate to generate heat that is transferred into the rigid plate, which can then be transferred to the wafer 150. In operation, the wafer support stage 110 supports the wafer 150 thereon. For example, the wafer support stage 110 may have a major surface 110a (or “surface 110a” or “mounting surface 110a”) on which the wafer 150 can rest during a heating operation. The wafer support stage 110 can transfer heat to the wafer 150 via contact with the wafer 150 on the surface 110a thereof. The heating element can increase temperature of the rigid plate on which the wafer 150 rests. Generally, temperature of the rigid plate may be selected to be above room or ambient temperature, and may be in a range of about 100° C. to about 500° C., including any suitable range within the stated range. Temperatures below about 100° C., such as between room temperature and 100° C. may also be used by the wafer support stage 110 to heat the wafer 150. The wafer support stage 110 may be in data communication with the controller 190. Temperature of the rigid plate may be selected via an electrical signal received from the controller 190 that can control heat output of the heating element(s).

The wafer support stage 110 can have a circular profile in the top view. Namely, the major surface 110a of the wafer support stage 110 on which the wafer 150 rests can be circular or substantially circular in shape. Diameter of the rigid plate may be larger than that the wafer 150. The rigid plate may be or include a metal having beneficial thermal conductivity, such as aluminum, copper, silver or the like. In some embodiments, the rigid plate is or includes ceramic. Other suitably thermally conductive materials for the rigid plate are also contemplated as embodiments herein.

The chamber 130 is positioned above the wafer 150 and the wafer support stage 110. The chamber 130 can include one or more of an upper wall 132 and a side wall 134. The upper wall 132 can have circular profile in the top view. Diameter of the upper wall 132 can be similar to or different than that of the wafer support stage 110. For example, the diameter of the upper wall 132 can be somewhat larger than that of the wafer support stage 110. The upper wall 132 can directly overlie the wafer support stage 110 so as to cover the wafer support stage 110. In some embodiments, a chamber heating element is positioned in the upper wall 132 and is operable to increase temperature of the upper wall 132.

The side wall 134 can extend downward from the upper wall 132. The side wall 134 has diameter that exceeds that of the wafer support stage 110, such that the side wall 134 surrounds the wafer support stage 110 albeit being positioned above the wafer support stage 110. Namely, the side wall 134 may have a ring shape in the top view.

A gas deflector 140 is mounted to the side wall 134 of the chamber 130. The gas deflector 140 may have circular profile in the top view and may have diameter similar to or the same as that of the side wall 134. The gas deflector 140 may include mounting holes defined therein, and the gas deflector 140 may be mounted to or attached to the side wall 134 via mounting screws (not shown) or another suitable mounting component. In some embodiments, a mounting ring or “protection ring” 136 is mounted to the gas deflector 140 and/or the side wall 134. For example, the mounting screws may extend through the mounting ring 136, the gas deflector 140 and partially or fully into the side wall 134. Side walls of the gas deflector 140 may be exposed, as depicted in FIG. 1A.

The chamber 130 is operable to cover the wafer 150 on the wafer support stage 110. For example, the chamber 130 can translate upward and downward along the vertical direction. In some embodiments, a chamber driver (not shown) is operable to drive the chamber 130 in the vertical direction, for example, by a motor or other suitable actuator. Position of the chamber 130 in the vertical direction can result in at least two different states, which can include a first state and a second state that are described in detail below.

In the first state, the chamber 130 (e.g., the mounting ring 136) is proximal the wafer support stage 110. For example, a lower end of the mounting ring 136 may be in contact with or within a short distance (e.g., a few millimeters) of a lower side wall 138 adjacent to or attached to the wafer support stage 110. In some embodiments, a gap may be present between an upper end of the side wall 138 and the lower end of the mounting ring 136. In the first state, a space 160 is formed above the wafer 150 between the wafer 150 and the gas deflector 140. The space 160 may have a height D1 between the surface 150a of the wafer 150 and the underside surface 140a of the gas deflector 140. The height D1 may be in a range of about 1 centimeter (cm) to about 3 cm.

In the second state, the chamber 130 may be separated from the wafer support stage 110. For example, separation distance between the mounting ring 136 and the lower side wall 138 may be sufficiently large to allow for placement or removal of the wafer 150 into or out of the apparatus 100, such as by a robot arm. In the second state, the space 160 is considered not to be formed above the wafer support stage 110. Namely, the space 160 above the wafer support stage 110 can be open to, for example, space of the housing in which the chamber 130 is positioned. Generally, in the second state, the apparatus 100 is not operable to heat the wafer 150 due to the loss of heat that would result from the chamber 130 and the wafer support stage 110 being separated by such a large distance. In the second state, the space 160 may have height that exceeds the height D1 that is present in the first state. Namely, the space 160 may have height that is greater than about 2 cm, as one example. The chamber 130 can be moved up and down in response to an electrical signal received from the controller 190. This is depicted by a signal line that runs from the controller 190 to the body of the chamber 130 in FIG. 1A.

During a heating operation, the controller 190 may control the chamber 130 to move downward toward the wafer support stage 110 to enter the first state. The space 160 is then defined over the wafer support stage 110. The space 160 is a space in which processing liquid on the wafer 150 can be heated to solidify (e.g., to soft bake) the processing liquid to form a film layer. The space 160 is defined by at least (i) the underside surface 140a of the gas deflector 140 facing the wafer surface 150a, (ii) the inner surface of the side wall 134, (iii) a mounting surface 110a of the wafer support stage 110, and (iv) other surfaces of the apparatus 100, such as inner surfaces of the mounting ring 136 and the lower side wall 138. In some embodiments, distance D1 between the underside surface 140a and the surface 150a along the vertical direction is in a range of about 1 centimeter (cm) to about 3 cm, such as about 2 cm.

One or more gas supply openings 180 can be defined in the wafer support stage 110. The gas supply opening(s) 180 are operable to transfer gas into the space 160. An exhaust opening 170 is defined in the chamber 130 above the space 160, such as in the upper wall 132. The exhaust opening 170 is operable to transfer gas out of the space 160, out of the apparatus 100, or both. In operation, during or after heating of the wafer 150 in the thermal processing apparatus 100, a gas may be introduced into the space 160 via the gas supply opening(s) 180, and may be pumped out of the space 160 via the exhaust opening 170. The gas deflector 140 is between the space 160 and the exhaust opening 170 and is operable to control (e.g., direct) flow of the gas from the space 160 to the exhaust opening 170. For example, presence of the gas deflector 140 may establish a pressure differential between the space 160 and the exhaust opening 170. In some embodiments, the pressure differential is in a range of about 10 pascals to about 30 pascals, such as about 20 pascals. For example, pressure in the exhaust opening 170 may exceed pressure in the space 160 by about 20 pascals or another suitable value. The gas deflector is or includes a deflector plate 141 having holes 142, 144, 146 defined therein. The holes 142, 144, 146 include a center hole(s) 142, periphery holes 146 and intermediate or middle holes 144 between the center hole(s) 142 and the periphery holes 146. Arrangement and dimensions of the holes 142, 144, 146 are described in greater detail with reference to FIGS. 3A-3C.

Briefly, the gas flows into the apparatus via the gas supply opening(s) 180, upward over an upper surface 150a of the wafer 150, through the gas deflector 140, into the exhaust opening 170 and out of the apparatus 100 via a pump 172. The pump 172 is in fluid communication with the exhaust opening 170. The holes 142, 144, 146 of the gas deflector 140 are beneficial to control flow of the gas through the space 160 to be uniform across the surface of the wafer 150, which can improve uniformity of cooling of the processing liquid during or after the heating process. Increased volume of the gas passing over the processing liquid results in faster cooling, which results in thinner thickness of the solidified film layer. Decreased volume of gas passing over the processing liquid results in slower cooling and thicker thickness of the solidified film layer. Uniform flow of the gas over the wafer surface 150a due to the gas deflector 140 results in improved uniformity of thickness of the solidified film layer.

The apparatus 100 includes the wafer lifting assembly 120, which is operable to move the wafer 150 down and up onto and off of the surface 110a of the wafer support stage 110. The wafer lifting assembly 120 includes support pins 122 and a driver 124. The support pins 122 support the wafer 150. The support pins 122 may extend through the wafer support stage 110 in the vertical direction. The driver 124 is operable to move the support pins 122 up and down by an actuator, which may be or include a motor, a lifting cylinder or the like.

The driver 124 can push up the support pins 122 to raise the wafer 150 to a first position that is above the surface 110a of the wafer support stage 110. The driver 124 can lower the support pins 122 to lower the wafer 150 to a second position that is on the surface 110a. Namely, the support pins 122 may extend to a level that is below the surface 110a when the wafer 150 is in the second position. The second position can be associated with heating the wafer 150, due to the wafer 150 being in contact with the surface 110a of the wafer support stage 110, which allows for heat transfer between the wafer support stage 110 and the wafer 150. The driver 124 is in data communication with the controller 190 and can extend or retract the support pins 122 in response to an electrical signal received from the controller 190.

In some embodiments, the wafer 150 comprises at least one of a substrate, a photomask, a semiconductor device, a dielectric layer, an epitaxial layer, a silicon-on-insulator (SOI) structure, a semiconductor layer, a conductive material layer, a die, etc. The wafer 150 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The wafer 150 comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the wafer 150 are within the scope of the present disclosure. In some embodiments, the wafer 150 has diameter that is about 300 millimeters (mm). In some embodiments, the wafer 150 has diameter that is about 200 mm or 150 mm. It should be understood that the term “wafer” includes the meaning of a substrate that may be at an intermediate stage of fabrication. For example, the wafer may include one or more integrated circuit chips separated horizontally from each other by a molding layer. The wafer having the molding layer may have a film layer (e.g., photoresist) formed thereon for subsequent patterning by which through-molding vias (TMVs) may be formed in and through the molding layer.

FIG. 1B illustrates a diagrammatic side view of a portion 155 of a wafer, in accordance with some embodiments. In some embodiments, the wafer includes three-dimensional (3D) integrations or heterogeneous integrations, which can include multiple chips stacked vertically to form compact and high-performing integrated circuit (IC) dies. Prior to system IC singulation to form the individual system ICs, the wafer may include an array of the portions 155 arranged side-by-side on and in a major surface thereof.

In some embodiments, the portion 155 includes a lower integration 157 and an upper integration 159 stacked vertically on the lower integration 157. The lower integration 157 can include one or more IC chips 1510, 1512, 1514, which may be the same as each other or different than each other. As an example, a first IC chip 1510 and a second IC chip 1512 can be a first type large scale integration (LSI) and a third IC chip 1514 can be a second type LSI different than the first type LSI. The first and second type LSIs can include one or more of logic LSIs, analog/mixed-signal LSIs, radio frequency (RF) LSIs, graphics processing LSIs, image signal processing LSIs, artificial intelligence (AI) accelerator LSIs, and the like.

The IC chips 1510, 1512, 1514 may be embedded in and separated from each other by a molding layer 1522. Top interconnects 1528 may be in electrical contact with the IC chips 1510, 1512, 1514 and extend to an upper surface of the lower integration 157 to make electrical connections with elements of the upper integration 159, such as IC chips 1500, 1502, 1504. Bottom interconnects 1524 may be in electrical contact with backsides of the IC chips 1510, 1512, 1514 and extend to a lower surface of the lower integration 157 to make electrical connections with bumps 1526.

The upper integration 159 includes IC chips 1500, 1502, 1504. In some embodiments, the IC chip 1500 can be a system-on-a-chip (SOC), such as an application processing unit (APU), central processing unit (CPU), graphics processing unit (GPU), or the like. The IC chips 1502, 1504 can be high-bandwidth memory (HBM) IC chips or other suitable IC chips. Electrical interconnections may be present between the IC chip 1500 and the IC chips 1502, 1504 via the IC chips 1510, 1514. The IC chip 1500 may be further electrically connected to the IC chip 1512. The IC chips 1502, 1504 may be electrically connected to the IC chips 1510, 1514. Electrical connections between the IC chips 1500, 1502, 1504 of the upper integration 159 and the IC chips 1510, 1512, 1514 of the lower integration 157 may be via the top interconnects 1528 and bumps 1530, which may be microbumps or other suitable interconnect structures.

A first encapsulation 1534 may be present between the bumps 1530 and between the IC chips 1500, 1502, 1504 of the upper integration 159. A second encapsulation 1532 may be present between adjacent pairs of the portions 155.

In some embodiments, it is beneficial to make electrical signal connections directly between bumps 1530 of the IC chips 1502, 1504 and the bumps 1526 on the backside of the lower integration 157. In such embodiments, the lower integration 157 may include through insulator vias (TIVs) or through molding vias (TMVs) 1520 that extend completely through the molding layer 1522. First ends of the TMVs 1520 may be in contact with the bumps 1530 and second ends of the TMVs 1520 may be in contact with the bumps 1526.

In a semiconductor process that forms the TMVs 1520, the IC chips 1510, 1512, 1514 may be embedded in the molding layer 1522. Then, first openings for the TMVs 1520 may be formed through the molding layer 1522 adjacent one or more of the IC chips 1510, 1512, 1514. The first openings may be formed via a suitable patterning operation, which may include forming a patterned resist layer including second openings therein, then extending the second openings of the resist layer through exposed portions of the molding layer 1522. Following formation of the first openings in the molding layer 1522, a suitable conductive material may be deposited to fill (entirely or partially) the first openings in the molding layer 1522. Excess material of the TMVs 1520 above the molding layer 1522 may be removed by a removal process, such as a chemical mechanical polishing (CMP) or the like. Formation of the first openings in which the TMVs 1520 are deposited can include formation of a resist layer similar to that described with reference to FIG. 1A. Due to inclusion of the gas deflector 140, uniformity of the resist layer that is patterned to form the TMVs 1520 is improved, which can improve uniformity of the TMVs 1520. In some embodiments, height L of the TMVs 1520 in the vertical direction is in a range of about 10 micrometers (um) to about 250 um.

FIG. 2A illustrates a schematic view depicting gas flow 290 during a thermal processing operation, in accordance with some embodiments. The gas flow 290 is illustrated and described with reference to the apparatus 100 of FIG. 1A, however the apparatus 100 depicted in FIG. 2A includes a gas deflector 140C that is different in some aspects than the gas deflector 140 of FIG. 1A. In FIG. 2A, some elements of the apparatus 100 are omitted from view for simplicity of illustration. For example, the wafer support stage 110 and the wafer lifting assembly 120 are omitted from the view illustrated in FIG. 2A.

As depicted by arrows in FIG. 2A, the gas flow 290 of gas begins below the wafer 150, proceeds along the surface of the wafer 150, continues through holes or “exhaust holes” 147, 149 of the gas deflector 140C and exits via the exhaust opening 170. In the gas deflector 140C, the holes 147 may be of the same or substantially the same radius and/or size as each other. In some embodiments, a hole 147 in the center of the deflector plate 141 can have size that is smaller than that of the holes 149. The holes 149 are outermost holes and are positioned at the periphery of the deflector plate 141. In some embodiments, no exhaust holes are present between the holes 149 and the outer edge 140b of the deflector plate 141. Mounting holes may be positioned between the holes 149 and the outer edge 140b. The mounting holes are filled with screws or other fasteners and are not operable to exhaust gas therethrough, and as such, should not be considered “exhaust holes.” Namely, it should be understood that “no exhaust holes are present between” does not require that no hole can be located between the outermost exhaust holes 149 and the outer edge 140b, such as when such hole is filled entirely or partially by a fastener or other element.

Due to the arrangement of the holes 147, 149 in which a smallest or smaller hole 147 is positioned at the center of the gas deflector 140C and largest or larger holes 149 are positioned at the periphery of the gas deflector 140C, regions of reduced gas flow or “stagnation regions” 292, 294 are present at the center of the wafer 150 and at the periphery of the wafer 150. The region 292 that has reduced gas flow is over a central region of the wafer 150. The region(s) 294 that has reduced gas flow is over the periphery of the wafer 150. As described with reference to FIG. 1A, reduced gas flow can result in thicker layer thickness, which can result in non-uniformity of thickness of a film layer (e.g., a resist layer) formed on the wafer 150. This is illustrated diagrammatically in the view of FIG. 2B.

FIG. 2B illustrates non-uniformity of thickness of a film layer 280 on a wafer 270, in accordance with some embodiments. The wafer 270 can be an embodiment of the wafer 150 and may be similar in most respects to the wafer 150 described with reference to FIGS. 1A-2A. Height(s) of the film layer 280 may not be drawn to scale in the view of FIG. 2B for clarity of illustration.

Due to reduced gas flow in the region 292 over the center 212 of the wafer 270 and in the region(s) 294 at the periphery of the wafer 270, the film layer 280 may have larger thickness in the center region 210 thereof and in a peripheral region(s) 240, 250, 260 thereof. This is illustrated by peaks 282, 284, which include a center peak 282 at the center 212 of the wafer 270 and a peripheral peak 284 at a periphery of the wafer 270, such as near the peripheral regions 240, 250. The wafer 270 may include the center region 210, a first intermediate region 220 surrounding the center region 210, a second intermediate region 230 surrounding the first intermediate region 220, and one or more peripheral regions 240, 250, 260 surrounding the second intermediate region 230. Each of the regions 210, 220, 230, 240, 250, 260 may have a ring profile in the top view, which is depicted in FIG. 2C.

As illustrated in FIG. 2B, the center peak 282 may have first height H1 and the peripheral peak 284 may have second height H2. In some embodiments, the first and second heights H1, H2 are about the same size as each other. In some embodiments, the first and second heights H1, H2 have different dimensions. For example, the first height H1 of the center peak 282 may exceed the second height H2 of the peripheral peak 284.

A valley(s) 286 may be present in the second intermediate region 230. The valley(s) 286 may be formed due to relatively higher gas flow rate in the second intermediate region 230, which can result in lower thickness of the film layer 280. The valley(s) 286 may have fourth height H4 that is less than the first and second heights H1, H2 at the center and peripheral regions 210, 240, 250, 260. Third height H3 of the film layer 280 in the first intermediate region 220 may be between the first and second heights H1, H2 and the fourth height H4. It should be understood that the heights H1, H2, H3, H4 may not be depicted to scale in FIG. 2B. Namely, differences in the heights H1, H2, H3, H4 may be less pronounced than is depicted in FIG. 2B.

To improve uniformity between gas flow in the regions 292, 294 and gas flow outside the regions 292, 294, exhaust holes and sizes thereof are arranged in some embodiments described below so that gas flow resistance decreases along a direction from the periphery of the wafer to the center of the wafer. To achieve the decrease in gas flow resistance, permeability of the gas deflector increases continuously along the direction from the periphery to the center. Embodiments of a gas deflector 300 in which the gas flow resistance decreases with proximity to the center of the gas deflector 300 are described with reference to FIGS. 3A-3C.

FIG. 3A illustrates a perspective view of a gas deflector 300, in accordance with some embodiments. The gas deflector 300 is an embodiment of the gas deflector 140 described with reference to FIG. 1A and may be similar in most respects to the gas deflector 140.

The gas deflector 300 includes a deflector plate 341 which is similar to the deflector plate 141 described with reference to FIG. 1A. The deflector plate 341 includes or defines openings or holes 342, 344, 346 therein. The holes 342, 344, 346 extend fully through the deflector plate 341 so that gas can pass therethrough. The holes 342, 344, 346 may have circular profile in a top view, though other profile shapes may be included instead of or in addition to the circular profile, such as ovals, squares, hexagons or other suitable shapes. The holes 342, 344, 346 include center hole(s) 342, intermediate holes 344 and peripheral holes 346. The center hole(s) 342 is arranged at or immediately adjacent the center of the major surface of the deflector plate 341. The intermediate holes 344 are arranged in concentric rings around the center hole(s) 342. The peripheral holes 346 are arranged in concentric rings around the intermediate holes 344. As depicted in FIG. 3A, the holes 342, 344, 346 include a single center hole 342 at the center of the deflector plate 341, five concentric rings of the intermediate holes 344 arranged outside the center hole 342, and two concentric rings of the peripheral holes 346 arranged outside the intermediate holes 344. Each ring of the intermediate holes 344 and each ring of the peripheral holes 346 has sixteen respective holes. In some embodiments, each ring may have fewer or more than sixteen holes, such as twelve holes, eighteen holes, twenty-four holes, or another suitable number of holes.

The holes 342, 344, 346 include holes of at least three different sizes. In some embodiments, the hole(s) 342 has size (e.g., diameter) that exceeds that of each of the holes 344, each of which has size (e.g., diameter) that exceeds that of each of the holes 346. As such, the holes 346 at the outermost periphery of the deflector plate 341 have the smallest size and the hole(s) 342 at the center of the deflector plate 341 has the largest size among the holes 342, 344, 346. The holes 342, 344, 346 may be arranged in lines that extend from the center of the deflector plate 341 toward an outer edge 341a of the deflector plate 341. A region 390 includes a single line of the holes 342, 344, 346 and is described in greater detail with reference to FIGS. 3B and 3C. FIG. 3A depicts sixteen lines of the holes 342, 344, 346, in which each of the lines includes the single center hole 342. In some embodiments, the number of lines can be less than or greater than sixteen, such as twelve, eighteen, twenty, twenty four, or another suitable number.

FIG. 3B illustrates a diagrammatic top view of the region 390 of the gas deflector 300 of FIG. 3A, in accordance with some embodiments. The region 390 may correspond to a line of the holes 342, 344, 346 as described with reference to FIG. 3A.

In some embodiments, the gas deflector 300 includes a center or “first” region 310, a peripheral or “third” region 330 and an intermediate or “second” region 320 between the center region 310 and the peripheral region 330. In some embodiments, the center region 310 extends radially outward from the center of the gas deflector 300 to a first distance that is about one quarter of the radius of the gas deflector 300 or another suitable value. In some embodiments, the intermediate region 320 extends radially outward from about one quarter of the radius to about three quarters of the radius of the gas deflector 300 or another suitable value. In some embodiments, the peripheral region 330 extends radially outward from about three quarters of the radius to about the radius of the gas deflector 300. In some embodiments, the radius of the gas deflector 300 is somewhat larger than that of the wafer (e.g., the wafer 150). For example, when the wafer 150 is a 300 mm type wafer having diameter of 300 mm, the radius of the gas deflector 300 may be somewhat larger than 150 mm, such as about 160 mm to about 200 mm.

As depicted in FIG. 3B, the center hole 342 in the center region 310 may be a largest hole of the holes 342, 344, 346. Each of the holes 342, 344, 346 may have area in a range of about 0.01 mm² to about 100 mm². In some embodiments, the hole 342 has area that exceeds area of each of the holes 344 by about 1.5 times to about 100 times. For example, when the hole 342 has area of about 100 mm², the holes 344 may each have area of about 1 mm² to about 67 mm². In some embodiments, each of the holes 344 has area that exceeds area of each of the holes 346 by about 1.5 times to about 100 times. For example, when the hole 344 has area of about 1 mm², the holes 346 may each have area of about 0.01 mm² to about 0.67 mm². A ratio of area of the hole 342 over area of the hole 344 can be referred to as a first ratio, and may be in a range of about 1.5 to about 100 as just described, or may be in another range, such as about 2 to about 50, about 3 to about 10, about 5 to about 20, or another suitable range within the range of about 1.5 to about 100.A ratio of area of the hole 344 over area of the hole 346 can be referred to as a second ratio, and may be in a range of about 1.5 to about 100 as just described, or may be in another range, such as about 2 to about 50, about 3 to about 10, about 5 to about 20, or another suitable range within the range of about 1.5 to about 100.

The first region 310 may include the hole 342 and one ring of holes 344, one hole 344 of which is depicted in the region 390 illustrated in FIG. 3B. A first distance D_{A} may separate the hole 342 and the hole 344 in the first region 310. In some embodiments, the first distance D_{A} exceeds about 15 mm. The first distance D_{A} exceeding about 15 mm can improve uniformity of gas flow rate over the region of the wafer 150 underlying the first region 310. Below about 15 mm, the uniformity of the gas flow rate may be insufficient to substantially improve the uniformity of thickness of the film layer formed on the wafer, such as the film layer 280 formed on the wafer 270.

The second region 320 may include at least four rings of holes 344. Four of the holes 344 are depicted in FIG. 3B. Neighboring pairs of the holes 344 may be offset from each other by a second distance D_{B}. The second distance D_{B} may be less than the first distance D_{A}. In some embodiments, the second distance D_{B} is in a range of about 5 mm to about 15 mm, such as about 5 mm to about 10 mm. Other ranges for the second distance D_{B} are also contemplated as embodiments herein. Generally, the second distance D_{B} is less than about 15 mm. Number of the rings of holes 344 in the second region 320 may be in a range of about 3 to about 6, with other ranges considered as embodiments herein. Distance between the hole 344 in the first region 310 and the hole 344 immediately adjacent thereto in the second region 320 may be less than the first and second distances D_{A}, D_{B}.

The third region 330 may include at least three rings of holes 346. Three of the holes 346 are depicted in FIG. 3B. Neighboring pairs of the holes 346 in the line depicted in region 390 may be offset from each other by a third distance D_{C}. The third distance D_{C} may be less than the first distance D_{A} and may be less than, equal to or greater than the second distance D_{B}. In some embodiments, the third distance D_{C} is in a range of about 2 mm to about 15 mm, such as about 5 mm to about 10 mm. Other ranges for the third distance D_{C} are also contemplated as embodiments herein. Generally, the third distance D_{C} is less than about 15 mm. Number of the rings of holes 346 in the third region 330 may be in a range of about 2 to about 6, with other ranges considered as embodiments herein.

In the embodiment described with reference to FIG. 3B, holes 342, 344, 346 of three different sizes are arranged in a manner in which largest hole(s) 342 is proximal or at the center of the gas deflector 300, second largest holes 344 are offset from the center, and smallest holes 346 are proximal the outer edge or most distal the center of the gas deflector 300. Including the three different sizes with the hole sizes decreasing with increased distance from the center is beneficial to improve uniformity of gas flow rate through the gas deflector 300 over the entire area of the wafer 150, 270 thereunder.

FIG. 3C illustrates a diagrammatic top view of the region 390 in which holes 342, 342A, 344, 344A, 344B, 344C, 346, 346A, 346B are arranged in a line extending radially outward from the center of the gas deflector 300 toward the outer edge of the gas deflector 300. Area of the holes 342, 342A, 344, 344A, 344B, 344C, 346, 346A, 346B decreases continually and gradually from the center toward the outer edge of the gas deflector 300, as illustrated by dashed lines 350, 352. In some embodiments, area of the hole 342 exceeds area of the hole 342A, which exceeds area of the hole 344, which exceeds area of the hole 344A, which exceeds area of the hole 344B, which exceeds area of the hole 344C, which exceeds area of the hole 346, which exceeds area of the hole 346A, which exceeds area of the hole 346B. Said another way, the area of the holes 342, 342A, 344, 344A, 344B, 344C, 346, 346A, 346B increases continually and gradually from the periphery or outer edge toward the center of the gas deflector 300, as illustrated by dashed lines 350, 352. The arrangement depicted in FIG. 3C has the holes 342, 342A, 344, 344A, 344B, 344C, 346, 346A, 346B that are of at least nine different sizes. In some embodiments, number of different sizes of holes 342, 344, 346 is at least three, such as at least four, at least five, at least six, at least seven, at least eight, at least nine, or more. Each ring of holes 344, 344A, 344B, 344C, 346, 346A, 346B can include sixteen holes all of which have substantially the same size. For example, a ring of the holes 344A may have sixteen (or a different number) of the holes 344A arranged in a ring, each of the holes 344A may have circular profile, and each of the holes 344A may have the same area, radius or the like.

In the embodiments described with reference to FIGS. 3B and 3C, the sizes of the holes 342, 344, 346 or the holes 342, 342A, 344, 344A, 344B, 344C, 346, 346A, 346B increase toward the center of the gas deflector 300 and decrease toward the periphery of or away from the center of the gas deflector 300. As such, holes more proximate the center have higher permeability and holes more distant from the center have lower permeability. Namely, flow resistance increases with distance from the center and flow permeability increases with proximity to the center. This type of arrangement reduces the formation and severity of stagnation regions in the space over the wafer, which improves uniformity of gas flow over the entire surface of the wafer, and thereby improves thickness uniformity of the film layer formed from the processing liquid layer on the wafer.

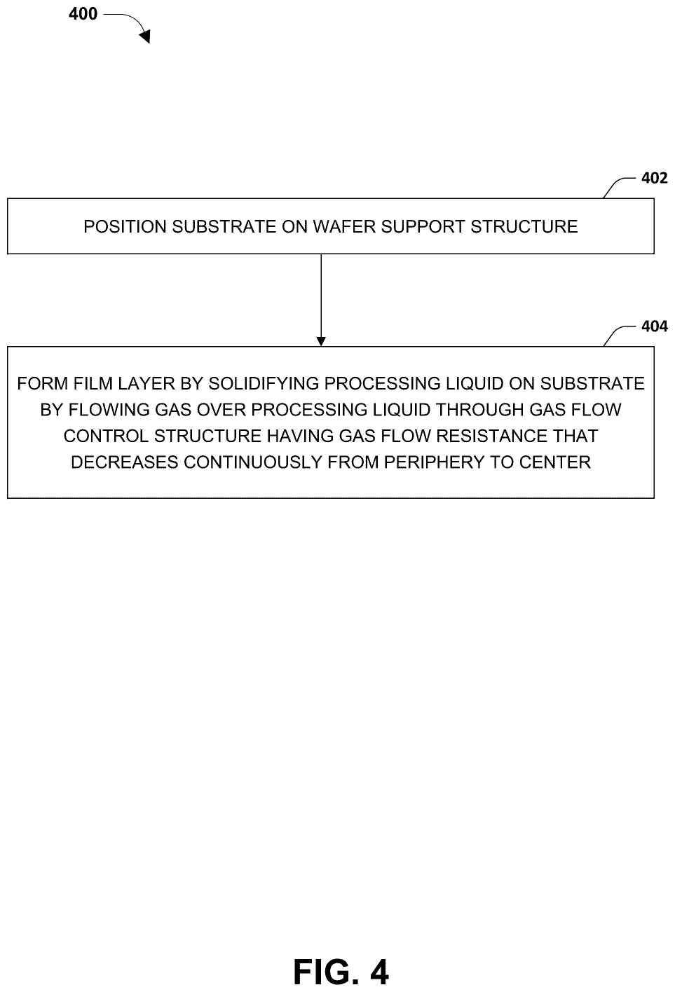

A method 400 is illustrated in FIG. 4 in accordance with some embodiments. At 402, the method 400 includes positioning a substrate on a wafer support structure, the substrate having a layer of processing liquid thereon. At 404, the method includes forming a film layer by solidifying the processing liquid by flowing a gas over a surface of the processing liquid, the flowing including drawing the gas away from the surface through a gas flow control structure over and separated from the wafer support structure, the gas flow control structure having gas flow resistance that decreases continuously along a direction from a periphery of the substrate to a center of the substrate.

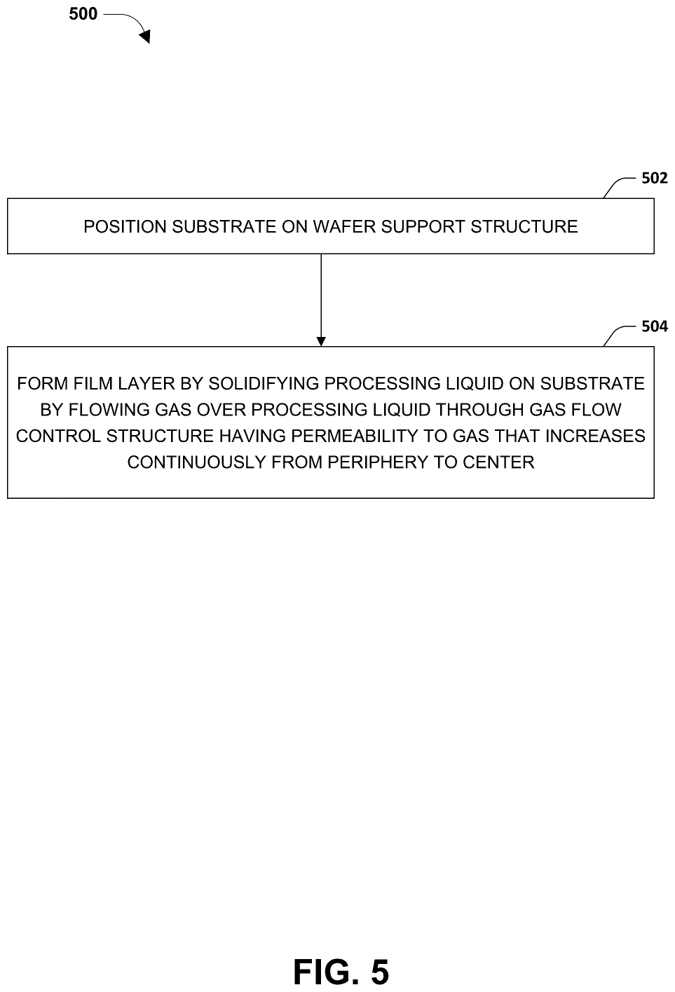

A method 500 is illustrated in FIG. 5 in accordance with some embodiments. At 502, the method 500 includes positioning a substrate on a wafer support structure, the substrate having a layer of processing liquid thereon. At 504, the method includes forming a film layer by solidifying the processing liquid by flowing a gas over a surface of the processing liquid, the flowing including drawing the gas away from the surface through a gas flow control structure over and separated from the wafer support structure, the gas flow control structure having gas permeability that increases continuously along a direction from a periphery of the substrate to a center of the substrate.

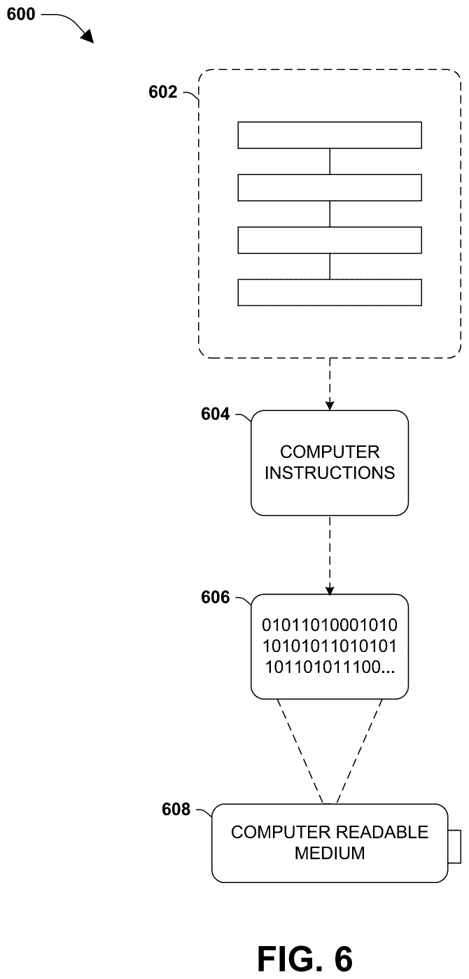

One or more embodiments involve a computer-readable medium comprising processor-executable instructions configured to implement one or more of the techniques presented herein. An exemplary computer-readable medium is illustrated in FIG. 6, wherein the embodiment 600 comprises a computer-readable medium 608 (e.g., a CD-R, DVD-R, flash drive, a platter of a hard disk drive, etc.), on which is encoded computer-readable data 606. This computer-readable data 606 in turn comprises a set of processor-executable computer instructions 604 configured to implement one or more of the principles set forth herein when executed by a processor. In some embodiments 600, the processor-executable computer instructions 604 are configured to implement a method 602, such as at least some of the aforementioned method(s) when executed by a processor. In some embodiments, the processor-executable computer instructions 604 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, an apparatus is provided. The apparatus includes: a wafer support structure; a chamber over the wafer support structure, the chamber defining an exhaust opening that overlies the wafer support structure; and a gas flow control structure between the wafer support structure and the exhaust opening. The gas flow control structure includes: a first region defining a first opening having a first size; a third region defining a plurality of third openings each having a third size, the first region being more proximal a center of the gas flow control structure than the third region; and a second region between the first region and the third region, the second region defining a plurality of second openings each having a second size, the second size exceeding the third size, the first size exceeding the second size.

In some embodiments, an apparatus is provided. The apparatus comprises: a wafer support structure operable to heat a wafer, the wafer support structure having a first surface operable to support the wafer thereon; and a gas flow control structure having substantially circular profile, the gas flow control structure being over and facing the first surface of the wafer support structure, the gas flow control structure being offset from the wafer support structure, the gas flow control structure being permeable by gas, permeability of the gas flow control structure increasing continuously along a direction from a periphery of the gas flow control structure to a center of the gas flow control structure.

In some embodiments, a method is provided. The method comprises: positioning a substrate on a wafer support structure, the substrate having a layer of processing liquid thereon; and forming a film layer by solidifying the processing liquid by flowing a gas over a surface of the processing liquid, the flowing including drawing the gas away from the surface through a gas flow control structure over and separated from the wafer support structure, the gas flow control structure having gas flow resistance that decreases continuously along a direction from a periphery of the substrate to a center of the substrate.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. An apparatus comprising:
a wafer support structure;
a chamber over the wafer support structure, the chamber defining an exhaust opening that overlies the wafer support structure; and
a gas flow control structure between the wafer support structure and the exhaust opening, the gas flow control structure including:
a first region defining a first opening having a first size;
a third region defining a plurality of third openings each having a third size, the first region being more proximal a center of the gas flow control structure than the third region; and
a second region between the first region and the third region, the second region defining a plurality of second openings each having a second size, the second size exceeding the third size, the first size exceeding the second size.

2. The apparatus of claim 1, wherein the wafer support structure is operable to heat a wafer supported thereon.

3. The apparatus of claim 1, wherein distance between the first opening and a second opening of the plurality of second openings that is immediately adjacent to the first opening is at least about 15 millimeters.

4. The apparatus of claim 1, wherein area of the first opening is less than about 100 square millimeters (mm²).

5. The apparatus of claim 1, wherein the third size exceeds about 0.01 mm².

6. The apparatus of claim 1, wherein the first opening, each of the plurality of second openings and each of the plurality of third openings have circular profile and the first size is a first diameter, the second size is a second diameter and the third size is a third diameter.

7. The apparatus of claim 1, wherein the gas flow control structure defines a plurality of fourth openings positioned between the third region and an outer edge of the gas flow control structure, and the apparatus includes a plurality of fasteners that extend through the fourth openings into the chamber.

8. An apparatus comprising:
a wafer support structure operable to heat a wafer, the wafer support structure having a first surface operable to support the wafer thereon; and
a gas flow control structure having substantially circular profile, the gas flow control structure being over and facing the first surface of the wafer support structure, the gas flow control structure being offset from the wafer support structure, the gas flow control structure being permeable by gas, permeability of the gas flow control structure increasing continuously along a direction from a periphery of the gas flow control structure to a center of the gas flow control structure.

9. The apparatus of claim 8, wherein the gas flow control structure includes a line of holes that extends from the center toward the periphery.

10. The apparatus of claim 9, wherein the line of holes includes at least three holes of different sizes.

11. The apparatus of claim 10, wherein the holes of the line of holes have at least eight different sizes that decrease with increased distance from the center.

12. The apparatus of claim 9, wherein a first hole of the line of holes that is located at the center is a largest hole of the line of holes.

13. The apparatus of claim 12, wherein a second hole of the line of holes that is immediately adjacent the first hole is offset from the first hole by at least 15 millimeters.

14. The apparatus of claim 13, wherein an area ratio of a first area of the first hole over a second area of the second hole is in a range of about 1.5 to about 100.

15. A method comprising:
positioning a substrate on a wafer support structure, the substrate having a layer of processing liquid thereon; and
forming a film layer by solidifying the processing liquid by flowing a gas over a surface of the processing liquid, the flowing including drawing the gas away from the surface through a gas flow control structure over and separated from the wafer support structure, the gas flow control structure having gas flow resistance that decreases continuously along a direction from a periphery of the substrate to a center of the substrate.

16. The method of claim 15, wherein drawing the gas through the gas flow control structure includes drawing the gas through a first hole, a second hole and a third hole of the gas flow control structure, the second hole being between the first hole and the third hole along a radius of the gas flow control structure, first size of the first hole exceeding second size of the second hole, the second size exceeding third size of the third hole, the third hole being between the second hole and an outer edge of the gas flow control structure.

17. The method of claim 16, wherein drawing the gas through the first hole, the second hole and the third hole includes drawing the gas through the first hole that is offset from the second hole by at least 15 millimeters, the first hole being immediately adjacent the second hole along the radius.

18. The method of claim 16, wherein drawing the gas through the first hole, the second hole and the third hole includes drawing the gas through the first hole having first area that is less than about 100 mm² and through the second hole having second area that exceeds about 0.01 mm².

19. The method of claim 15, wherein drawing the gas through the gas flow control structure includes drawing the gas through the gas flow control structure including at least eight holes, each of the eight holes being of a different size.

20. The method of claim 15, further comprising:
forming first openings in the film layer by patterning the film layer;
forming second openings in a molding layer of the substrate through the first openings; and
forming respective through-molding vias in the second openings.
